(19) United States
(12) Patent Application Publication
(10) Pub. No.: US 2015/0115872 A1
(43) Pub. Date: Apr. 30, 2015

(54) Power Converter

(71) Applicant: EH Europe GMBH, Zurich (CH)

(72) Inventors: David Letombe, Arras (FR); M. Francios Beaucamp, Arras (FR); Mohamed Kechmire, Arras (FR)

(21) Appl. No.: 14/388,611

(22) PCT Filed: Mar. 26, 2013
(86) PCT No.: PCT/EP2013/056439

§ 371 Date: Sep. 26, 2014

(30) Foreign Application Priority Data
Mar. 30, 2012 (EP) 12305380.3

(51) Int. Cl. G01R 31/36; G01R 19/00; G01R 21/00; G01R 21/06; H02J 7/02; H02J 7/00

(52) U.S. Cl. CPC G01R 31/3648; H02J 7/02; H02J 7/007; G01R 21/006; G01R 21/06; G01R 31/3624; G01R 19/00
USPC 320/107; 320/137; 702/64; 702/60; 702/63

(57) ABSTRACT

The invention relates to a method and apparatus for calculating the input current being drawn by a power converter. The power converter may be connected to and charging a battery and the method includes the steps of measuring the current and voltage being supplied to the battery, along with the frequency at which the power converter is operating. The voltage being supplied to the power converter may be calculated using a pre-determined relationship with the current and voltage being supplied to the power converter and the frequency of operation. The voltage being supplied to the converter may then be used to calculate the current being drawn by the converter.

### FIELD OF THE INVENTION

The present invention concerns a power converter. More particularly, but not exclusively, this invention concerns a battery charger comprising a power converter and a method of operation thereof.

### BACKGROUND OF THE INVENTION

Industrial users of large batteries, for example, forklift truck batteries, require charging facilities to recharge the batteries once they have been depleted through use. The depleted batteries are connected to battery chargers, which are in turn connected to a mains electricity supply to provide the necessary electrical energy to recharge the batteries. Typically the mains electricity supply to the battery charging unit is alternating current, which is converted by a power converter in the battery charging unit, and a direct current is supplied to the battery for recharging. Depending on the individual battery being charged, there may be an optimum charging profile in which the voltage and current supplied to the battery varies over time.

Power supply companies may limit the maximum current that an industrial user may draw from the mains electricity supply network. This may be in order to balance the load on the mains electricity supply network, so that the power taken by the industrial user does not cause supply problems, for example, brownout or blackout, for other users. There may be financial penalties for users that exceed their maximum current limit.

In order that a battery may be charged using the optimum charging profile, the voltage and current supplied to the battery may be monitored. The battery charger may then adjust the level of current it is drawing from the mains supply in order to achieve the desired charging profile. However, due to losses in the charger, in order to obtain the necessary power output, the power input into the charger must be greater than the required output. This may result in the charger attempting to draw a larger current than allowed by the electricity supplier.

The user may attempt to avoid exceeding the maximum current allowance by monitoring the current drawn by the charging unit. However, it is both difficult and expensive to provide measuring units suitable for monitoring the large input current (and voltage) taken by the charging unit.

The present invention seeks to mitigate the above-mentioned problems.

### SUMMARY OF THE INVENTION

The invention provides, according to a first aspect, a method of calculating the input current being drawn by a power converter (Iₘₐᵢₙₛ), the power converter being connected to and charging a battery, the method comprising the steps of: measuring the voltage being supplied to the battery (V_{bat}); measuring the current being supplied to the battery (I_{bat}); measuring the frequency at which the power converter is operating (f_{converter}); calculating the voltage supplied to the power converter (Vₘₐᵢₙₛ) using a pre-determined relationship between V_{bat}, I_{bat}, and f_{convertor}, and Vₘₐᵢₙₛ; and using the value of Vₘₐᵢₙₛ to calculate Iₘₐᵢₙₛ.

The method allows the current being drawn by the power converter (Iₘₐᵢₙₛ) to be calculated without requiring that the current is directly measured. The power converter may be regulated such that the current drawn does not exceed a maximum level. This may allow a user of the power converter to avoid fines for exceeding a maximum allowed current level. This may also protect the power system supplying the power converter by preventing excess power demands from the power converter.

The power converter may be part of a battery charging unit. The battery charging unit may comprise a plurality of power modules, each power module including a power converter.

The method may include the step of calculating the power output of the power convertor (Pₒᵤₜ).

The method may include the step of calculating the power input into the power converter (Pᵢₙ). Pᵢₙ may be calculated using the value of Pₒᵤₜ and the average efficiency of the power converter (η). The average efficiency of the power converter (η) may be determined by testing the power converter during the manufacturing and calibration stage. The power converter may be tested using 400V or 480V AC. The tests may be undertaken from 10% load to 100% load of the power converter.

The step of calculating Iₘₐᵢₙₛ may include using the power factor for the power converter. The power factor may be determined by testing the power converter during the manufacturing and calibration stage. The power converter may be tested using 400V or 480V AC. The tests may be undertaken from 10% load to 100% of the power converter.

The steps of measuring V_{bat} and I_{bat} may be undertaken by a measurement device associated with the battery. The measurement device may be arranged to communicate V_{bat} and I_{bat} wirelessly.

The calculation steps may be carried out by a control module associated with the power converter. The control module may be arranged to receive the measurements of V_{bat} and I_{bat} wirelessly.

Measuring V_{bat} and I_{bat} directly as supplied to the battery terminals and wirelessly communicating the measurements to the control module removes any current and/or voltage loss that would occur in battery cables.

A second aspect of the invention provides a battery charger, the battery charger comprising a master controller and a plurality of power modules, each power module comprising a power converter and being configured to draw electrical power from a mains power source and supply electrical power to a battery, wherein the master controller is arranged to determine the current being drawn by each of the power modules during a battery charging process as set out with regards to the method as described above.

A third aspect of the invention provides a method of charging a battery, comprising the steps of: connecting a battery to a battery charger, controlling the power supplied to the battery by the battery charger, wherein the power drawn by the battery charger is limited to a maximum level and the power supplied to the battery by the battery charger is controlled in dependence on this maximum level, and the power being drawn by the battery charger is predicted by monitoring the power being supplied to the battery.

It will of course be appreciated that features described in relation to one aspect of the present invention may be incorporated into other aspects of the present invention. For example, the method of the invention may incorporate any of the features described with reference to the apparatus of the invention and vice versa.

### DESCRIPTION OF THE DRAWINGS

Embodiments of the present invention will now be described by way of example only with reference to the accompanying schematic drawings of which:

FIG. 1 shows a schematic representation of a battery charging unit according to a first embodiment of the invention;

FIG. 2 shows a schematic representation of the connections between a master controller and power modules as shown in FIG. 1;

FIG. 3 shows a schematic representation of a communications network between a battery charging unit as described with regards to FIGS. 1 and 2, and a battery;

FIG. 4 shows an algorithm used to determine the current and voltage levels supplied by a battery charging unit;

FIG. 5 shows a schematic representing the regulation loops for a charging unit according to the invention;

FIG. 6 shows a graphical representation of the values measured for output regulation of a charging unit;

FIG. 7 sets out the algorithm used during the power output regulation of a charging unit;

FIG. 8 is a graphical representation of the relationship between the frequency of the power converter and Vₘₐᵢₙₛ at several output currents;

FIG. 9 shows an algorithm used to calculate Iₘₐᵢₙₛ;

FIG. 10 shows the load profile of a modular battery charger operating with three modules at full load; and

FIG. 11 shows the load profile of a modular battery charger operating with three modules at full load and one module at 1% load.

### DETAILED DESCRIPTION

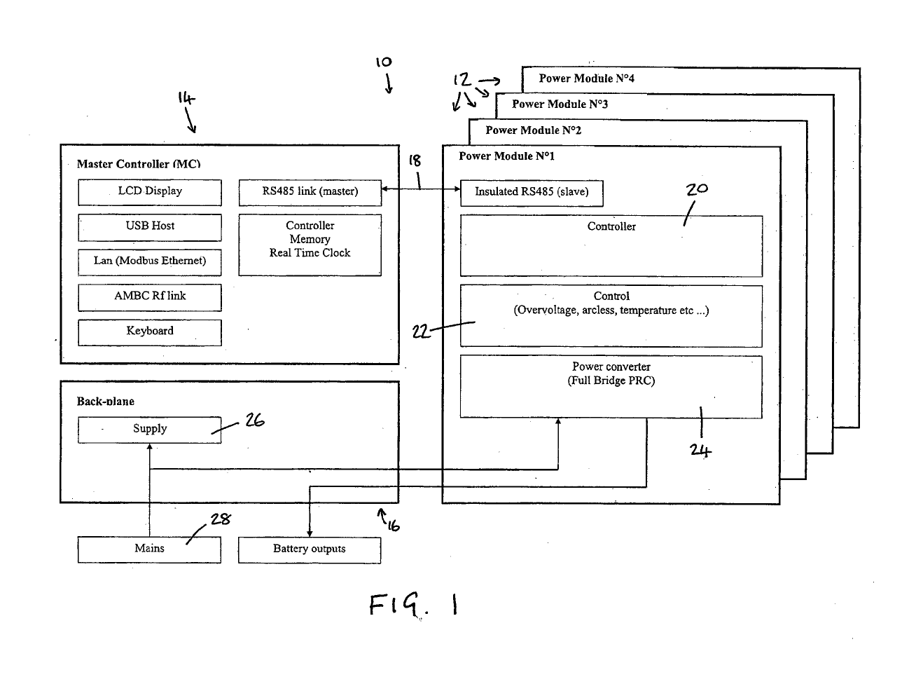

FIG. 1 shows a modular battery charging unit 10, comprising a plurality of power modules 12, a master controller 14, and a back-plane 16. The master controller 14 is connected to each power module by an RS485 network, such that each power module 12 is a slave of the master controller 14. Each power module 12 comprises a controller 20, a monitor unit 22, and a power converter 24. In this case the power converter 24 is a full-bridge power resonant converter. In alternative embodiments the power converter may be any converter which uses the switching frequency to adjust power output. Examples of such converters include series resonant converters and parallel resonant converters. The back-plane 16 comprises a supply unit 26 configured for connection to the mains supply 28. Each of the power modules 12 is connected to the back-plane 16 such that the supply 26 is arranged to provide electricity to the power modules 12.

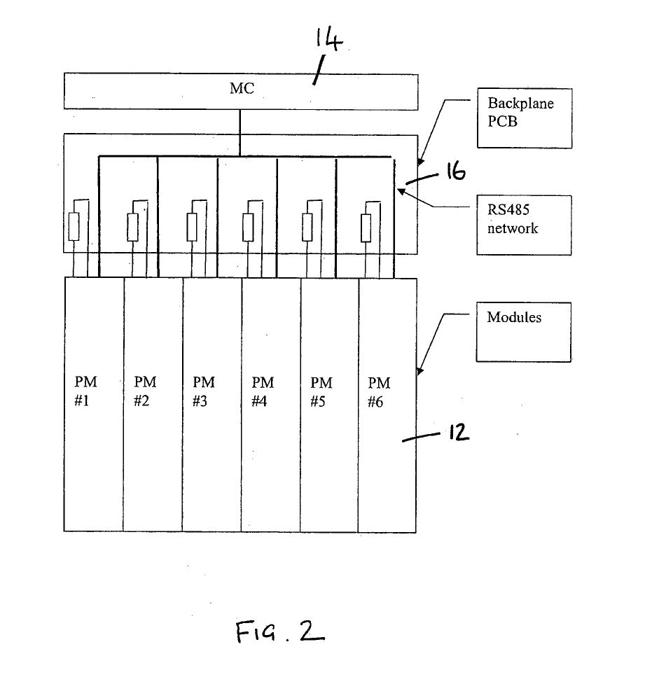

FIG. 2 shows a schematic representation of connections between the master controller 14, the plurality of power modules 12 (in this case, six power modules), and the back-plane 16. The master controller exchanges digital data with the power modules 12 using a half-duplex RS485 network. Each of the power modules 12 and the master controller are insulated. The communications protocol used on the network is ModBus RTU. The back-plane is a printed circuit board (PCB) arranged such that each power module 12 is allocated an individual address by using a fixed resistor on the PCB, each power module 12 having a resistor of different value in order that the address is unique. The master controller 14 may read the following data from each power module: output voltage, output current, time elapsed since power module switched on, fault warnings, temperature (any or all of ambient temperature, semiconductor heat sink temperature, bus bar temperature). The master controller 14 may write the following data to each power module: requested output voltage, requested output current, requested current slope. Only two functions of the ModBus protocol are implemented in the master controller 14 and the power modules 12, namely: Function 3 (or 4)—read of data from the power modules 12 to the master controller 14, and Function 16—write of data from the master controller 14 to the power modules 12. These read/write functions may be undertaken when a battery charging process is initiated. Each power module 12 is thereby a programmable voltage or current source, with all of the operational parameters being given by the master controller 14.

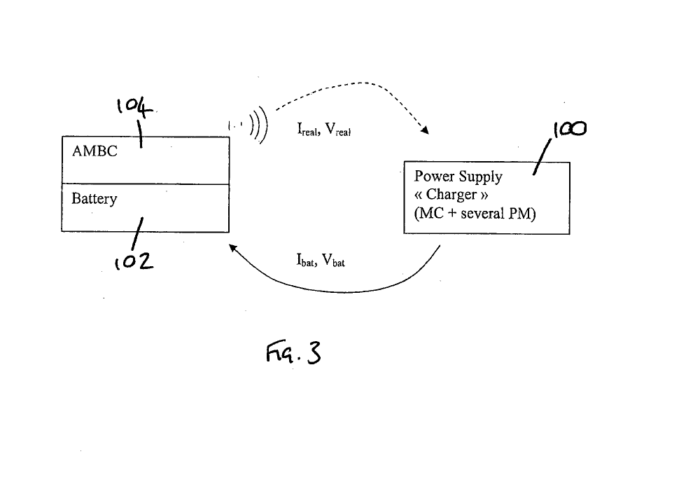

FIG. 3 shows a schematic representation of a communications network between a battery charging unit 100 as described with regards to FIGS. 1 and 2 and a battery 102 connected to the battery charging unit 100 for charging. The battery 102 includes a battery control device 104 arranged to detect several parameters of the battery, including: battery voltage, charging (or discharging) current, internal temperature of the battery, and water level if a flooded battery. The battery control device 104 includes a radio frequency transceiver arranged to be able to wirelessly communicate with the master controller of the charging unit 100. Such a battery control device could be the commercially available EnerSys WI-IQ device. The WI-IQ is available from EnerSys EMEA, EH Europe GmbH, Löwenstrasse 32, 8001 Zürich, Switzerland, and additional Enersys Motive Power Sales entities across the World. Providing the battery control device 104 with wireless communication is advantageous over a wired system as it allows voltage regulation without the influence of the length and section of the battery cables resulting in voltage losses in the readings. Instead, the voltage and current supplied to the battery 102 is measured directly at the terminals of the battery and then transmitted to the charging unit 100. As can be seen, the charging unit 100 supplies the battery 102 with a current I_{bat} and a voltage V_{bat} and the battery control device 104 detects the current and voltage and sends back the true readings of current (Iᵣₑₐₗ) and voltage (Vᵣₑₐₗ) which because the measurements are taken directly at the battery, correspond to V_{bat} and I_{bat}.

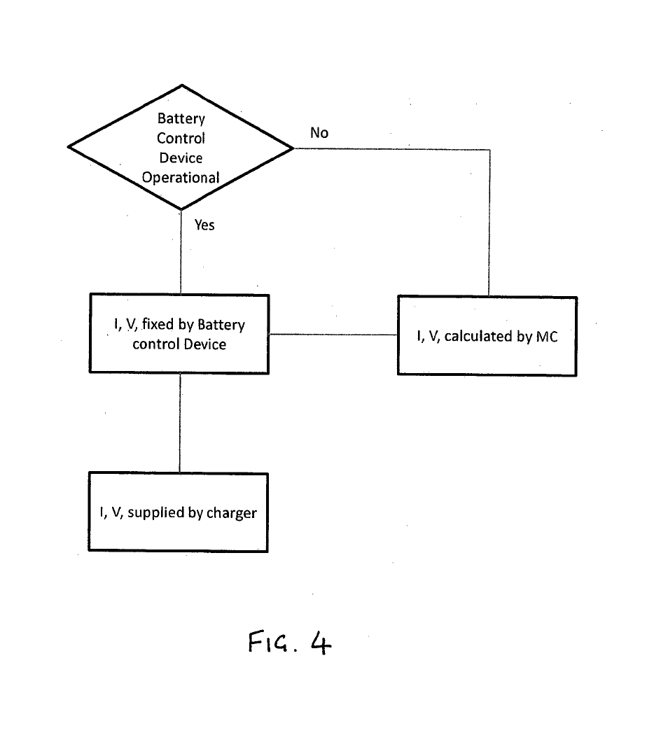

FIG. 4 shows the algorithm the master controller 14 runs through when the charger 100 is first connected to a battery 102. Initially, the master controller 14 sends a signal to the battery control device 104. Assuming the battery control device 104 is installed on the battery 102 and is operating correctly, a return signal is sent to the master controller 14. If the battery control device 104 is operational, the current and voltage supplied to the battery 102 is set by the battery control device 104 and supplied to the battery 102 by the charger 100. If the master controller 14 fails to connect to a battery control device 104, the current and voltage supplied to the battery 102 is set by the master controller 14, and then supplied to the battery 102 by the charger 100.

If the master controller 14 fails to connect to a battery control device 104, the voltage supplied to the battery is calculated as follows. Voltage (Vᵢ) and current (Iᵢ) are measured at the output of each of the power modules 12, where there are n modules in the bank of modules. The cable resistance of the bank of modules connected to the battery is denoted by R. The value of R is calculated by testing the bank of modules during the set up of the apparatus. These values are digitally converted and transmitted to the master controller 14. For each bank of power modules 12 the current is summarised:

$$Global current delivered by system \text{:} I = {\sum }_{i = 1}^{i = n} {I}_{i}$$

The reference voltage calculated by the master controller 14 is then calculated using:

$$Reference voltage \text{:} {V}_{out} \frac{{\sum }_{i = 1}^{i = n} {V}_{i} {I}_{i}}{{\sum }_{i = 1}^{i = n} {I}_{i}}$$

The voltage supplied to the battery (V_{bat}) can then be calculated by:

V_{bat}=Vₒᵤₜ−RI

The master controller 14 is arranged to regulate the output of the charger 100. In order to do this, the master controller is arranged to control the frequency of the power converters of each of the power modules that are being used. The output power of the converter/converters is inversely proportional to the frequency of operation.

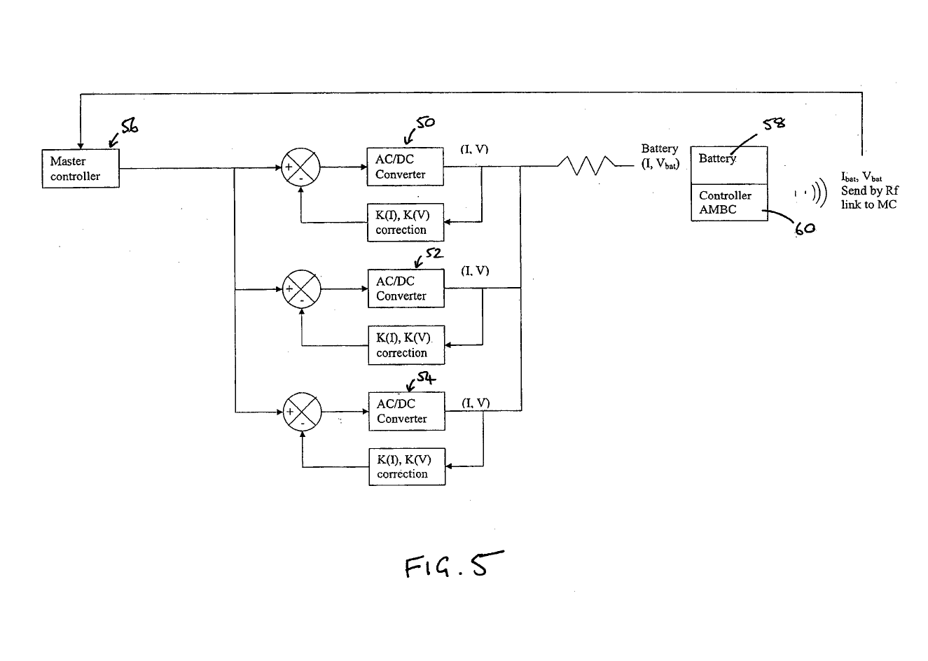

FIG. 5 is a schematic showing the regulation loops used to regulate the output of the power modules and the master controller and power modules. In this embodiment, three power modules 50, 52, 54, are connected to a master controller 56. The power modules 50, 52, 54, are connected to a battery 58 such that they supply a current (I_{bat}) and voltage (V_{bat}) to the battery 58. A battery control device 60 is associated with the battery 58 and monitors the current (I_{bat}) and voltage (V_{bat}) supplied to the battery 58. The battery control device 60 wirelessly communicates these values back to the master controller 56. The battery control device 60 may also be arranged to determine the charge profile required by the battery 58 and monitor the temperature of the battery 58. As can be seen in FIG. 5, each of the power modules 50, 52, 54, includes a regulation loop in which the output current and voltage is monitored with corrective feedback provided if necessary. Further details are given below.

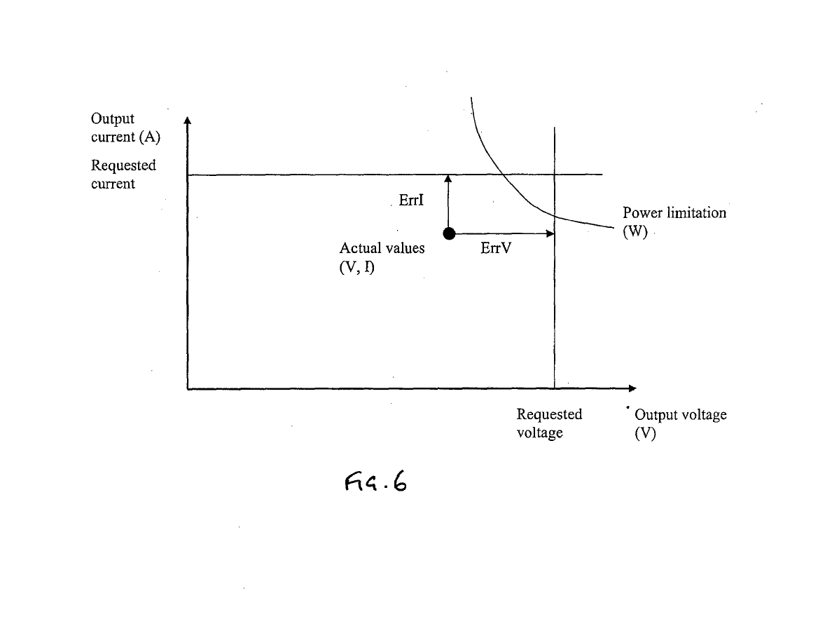

FIG. 6 shows how the output of each module may be regulated. The output of each module is measured and the actual monitored values are indicated by (V,I) in FIG. 6. The requested current and voltage can be seen to be different and the difference between each of these values compared to the real, measured, values is represented by ErrI and ErrV. The measured values V and I may also be used to calculate any error between the actual output power and requested output power of the power module. The master controller 56 directly controls the frequency of operation of the converters of each power module, with the output power being inversely proportional to the frequency of operation. The level of regulation required by the power modules is proportional to the error between the requested output values and the real, measured, values that are output by the power module.

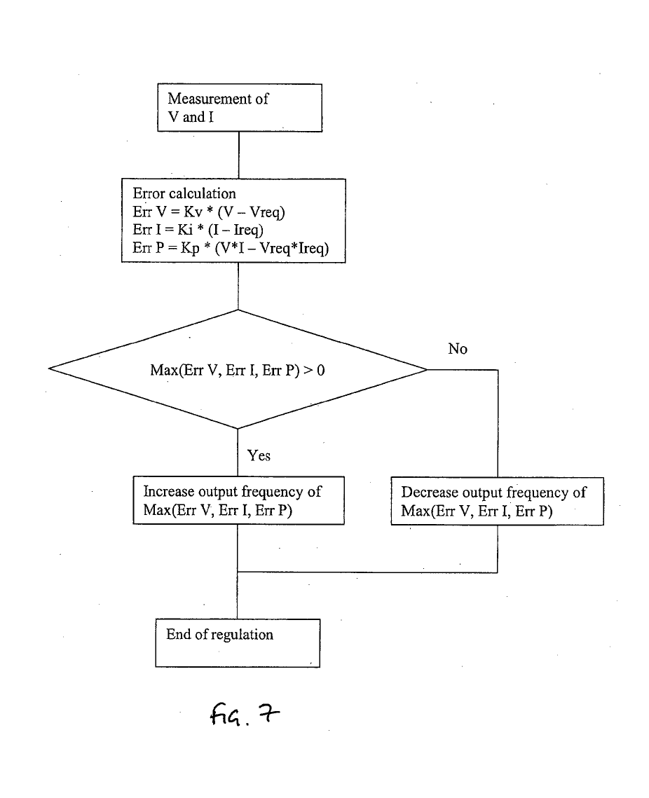

FIG. 7 shows the algorithm that is used to calculate the error between the requested current, voltage, and power output and the measured current, voltage, and power output. The voltage and current output are measured and the error between the requested values and measured values calculated. If one or more of the three calculated errors is positive, the regulation loop increases the frequency of operation of the power module. If all of the calculated errors are negative, the regulation loop decreases the frequency of operation of the power module.

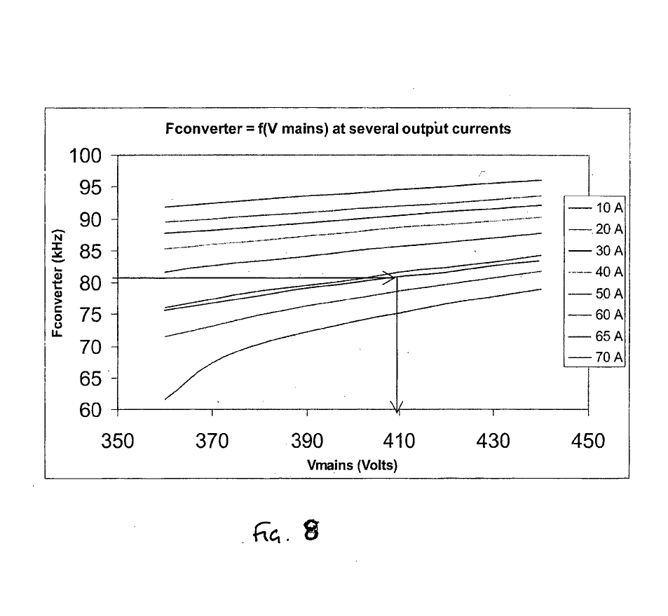

FIG. 8 is a graph showing the relationship between converter frequency and mains input voltage, represented by a plurality of curves, each curve showing measurements taken at a different output current, from 10 A to 70 A. The graph indicates the relationship between the frequency of the converter (F_{converter}) to Vₘₐᵢₙₛ. These values are determined by testing the converter during the manufacture and calibration process and are stored in the master controller for use during operation of the converter. The testing of the power converter during the manufacture and calibration process is relatively routine and will be easily undertaken by the person skilled in the art, who will also appreciate that several testing routines may be used to determine the power converter characteristics. As such, the details of the testing and calibration procedure are not provided herein. Each power module is configured to operate such that the same output current is produced by the same frequencies, to an accuracy of ±3%. The master controller may, from knowing the frequency of the converter and the current being output by the converter, calculate the corresponding mains voltage. In the example shown in FIG. 5, the measured output current is 62 A and the frequency of the converter is 81 kHz. The master controller calculated the curve for 62 A as an extrapolation of the measured curves for 60 A and 65 A. On this curve it can be seen that for a frequency of 81 kHz, the mains voltage will be 410V.

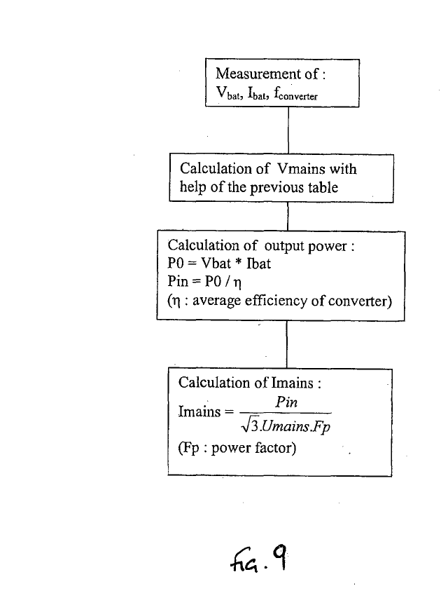

FIG. 9 shows the algorithm that is used by the master controller 14 to calculate the mains current (Iₘₐᵢₙₛ) being drawn by the charger. As has been set out previously, the values of V_{bat}, I_{bat}, and f_{converter} are measured. Using the graph and method shown and described with reference to FIG. 5, Vₘₐᵢₙₛ is calculated. The power output of the charger Pₒᵤₜ is calculated as:

Pₒᵤₜ=V_{bat}I_{bat}

The power input into the charger can be calculated by knowing the average efficiency of the power converters (η):

Pᵢₙ=Pₒᵤₜη

As previously stated, the average efficiency of the power converters is calculated during the manufacture and calibration process. Finally, the main current may be calculated by knowing Pᵢₙ, Vₘₐᵢₙₛ, and the power factor (Fp) of the power converters:

$${I}_{mains} = \frac{{P}_{in}}{\sqrt{3 {V}_{in} Fp}}$$

The power factor is calculated during the manufacture and calibration process. Using the calculated Iₘₐᵢₙₛ, the master controller may regulate the demands of the power modules on the mains supply such that the current drawn from the mains supply does not exceed a predetermined level. This will ensure that the user does not exceed the maximum current level that is set by the electricity supplier and so will not risk any penalty fees. It also protects the mains supply as excessive power demands will not be made by the battery charger.

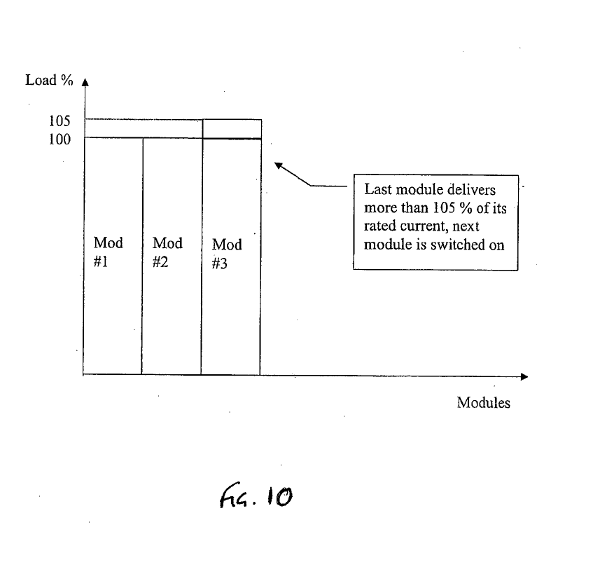

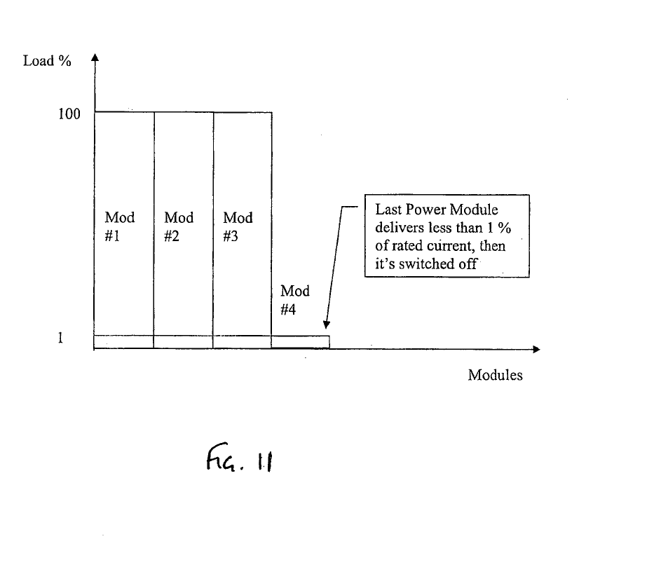

The power modules operate most efficiently at full load. Therefore, in order to most efficiently charge a battery, as many power modules as possible must be operated at full load. The supply to the battery is built up such that each of power modules is operated at full load, until 105% of full load is being demanded from that power module, at which point an additional power module is activated. This can be seen in FIG. 10 where the first two power modules are operating at 100% and the third power module is operating at 105%. This will trigger a fourth power module to be activated. When the load on a power module drops to less than 1% of the maximum load, the module is switched off. This can be seen in FIG. 11 where the fourth power module is operating at 1% and will be switched off as a result.

Whilst the present invention has been described and illustrated with reference to particular embodiments, it will be appreciated by those of ordinary skill in the art that the invention lends itself to many different variations not specifically illustrated herein. By way of example only, certain possible variations will now be described.

Additional embodiments of the invention may comprise any power supply using the switching frequency to adjust the output power. Example applications may be in the lighting industry, as applied to a telecommunications rectifier, or an uninterruptible power supply. Where in the foregoing description, integers or elements are mentioned which have known, obvious or foreseeable equivalents, then such equivalents are herein incorporated as if individually set forth. Reference should be made to the claims for determining the true scope of the present invention, which should be construed so as to encompass any such equivalents. It will also be appreciated by the reader that integers or features of the invention that are described as preferable, advantageous, convenient or the like are optional and do not limit the scope of the independent claims. Moreover, it is to be understood that such optional integers or features, whilst of possible benefit in some embodiments of the invention, may not be desirable, and may therefore be absent, in other embodiments.

1. A method of calculating the input current being drawn by a power converter (Iₘₐᵢₙₛ), the power converter being connected to and charging a battery, the method comprising the steps of:
measuring the voltage being supplied to the battery (V_{bat});
measuring the current being supplied to the battery (I_{bat});
measuring the frequency at which the power converter is operating (f_{converter});
calculating the voltage supplied to the power converter (Vₘₐᵢₙₛ) using a pre-determined relationship between V_{bat}, I_{bat} and f_{convertor}, and Vₘₐᵢₙₛ; and
using the value of Vₘₐᵢₙₛ to calculate the Iₘₐᵢₙₛ.

2. A method as claimed in claim 1, including the step of calculating the power output of the power convertor (Pₒᵤₜ).

3. A method as claimed in claim 1, including the step of calculating the power input into the power converter (Pᵢₙ).

4. A method as claimed in claim 3, including the step of calculating the power output of the power convertor (Pₒᵤₜ), wherein Pᵢₙ is calculated using the value of Pₒᵤₜ and the average efficiency of the power converter (η).

5. A method as claimed in claim 1, wherein the step of calculating Iₘₐᵢₙₛ includes using the power factor for the power converter.

6. A method as claimed in claim 1, wherein the steps of measuring V_{bat} and I_{bat} are undertaken by a measurement device associated with the battery.

7. A method as claimed in claim 6, wherein the measurement device is arranged to communicate V_{bat} and I_{bat} wirelessly.

8. A method as claimed in claim 1, wherein the calculation steps are carried out by a control module associated with the power converter.

9. A method as claimed in claim 8, wherein the control module is arranged to receive the measurements of V_{bat} and I_{bat} wirelessly.

10. A battery charger, the battery charger comprising a master controller and a plurality of power modules, each power module comprising a power converter and being configured to draw electrical power from a mains power source and supply electrical power to a battery, wherein the master controller is arranged to determine the current being drawn by the power modules during a battery charging process as set out with regards to the method as claimed in claim 1.

11. A method of charging a battery, comprising the steps of:
connecting a battery to a battery charger,
controlling the power supplied to the battery by the battery charger,
wherein the power drawn by the battery charger is limited to a maximum level and the power supplied to the battery by the battery charger is controlled in dependence on this maximum level, and the power being drawn by the battery charger is calculated by monitoring the power being supplied to the battery.
